(19) United States
(12) Patent Application Publication
(10) Pub. No.: US 2021/0280623 A1
(43) Pub. Date: Sep. 9, 2021

(54) PHASE DETECTION PIXELS WITH STACKED MICROLENSES

(71) Applicant: SEMICONDUCTOR COMPONENTS INDUSTRIES, LLC, Phoenix, AZ (US)

(72) Inventors: Ulrich BOETTIGER, Garden City, ID (US); Stanley MICINSKI, Meridian, ID (US)

(73) Assignee: SEMICONDUCTOR COMPONENTS INDUSTRIES, LLC, Phoenix, AZ (US)

(21) Appl. No.: 16/808,066

(22) Filed: Mar. 3, 2020

(51) Int. Cl. H01L 27/146

(52) U.S. Cl. CPC H01L 27/14627; H01L 27/14609

(57) ABSTRACT

An image sensor may include one or more phase detection pixel groups. A phase detection pixel group may include at least two phase detection pixels with respective photosensitive areas and a per-group microlens that covers all of the phase detection pixels in that group. Each phase detection pixel may have an asymmetric response to incident light. The phase detection pixel group may also include per-pixel microlenses that each cover a respective photosensitive area of a phase detection pixel. The per-group microlens may overlap the per-pixel microlenses. A low-index filler may be interposed between the per-group microlens and the per-pixel microlenses. The per-pixel microlenses may be incorporated into phase detection pixel groups in both front-side illuminated image sensors and back-side illuminated image sensors. The phase detection pixel groups may have a 2×2 arrangement.

### BACKGROUND

This relates generally to imaging systems and, more particularly, to imaging systems with phase detection capabilities.

Modern electronic devices such as cellular telephones, cameras, and computers often use digital image sensors. Imager sensors (sometimes referred to as imagers) may be formed from a two-dimensional array of image sensing pixels. Each pixel receives incident photons (light) and converts the photons into electrical signals. Image sensors are sometimes designed to provide images to electronic devices using a Joint Photographic Experts Group (JPEG) format.

Some applications such as automatic focusing and three-dimensional (3D) imaging may require electronic devices to provide stereo and/or phase detection capabilities. For example, to bring an object of interest into focus for an image capture, an electronic device may need to identify the distances between the electronic device and object of interest. To identify distances, conventional electronic devices use complex arrangements. Some arrangements require the use of multiple image sensors and camera lenses that capture images from various viewpoints. Other arrangements require the addition of lenticular arrays that focus incident light on sub-regions of a two-dimensional pixel array. Due to the addition of components such as additional image sensors or complex lens arrays, these arrangements lead to reduced spatial resolution, increased cost, and increased complexity.

It would therefore be desirable to be able to provide improved imaging systems with phase detection capabilities.

### BRIEF DESCRIPTION OF THE DRAWINGS

FIG. 1 is a diagram of an illustrative electronic device having an image sensor in accordance with an embodiment.

FIG. 2 is a diagram of an illustrative pixel array and associated readout circuitry for reading out image signals in an image sensor in accordance with an embodiment.

FIG. 3A is a cross-sectional side view of illustrative phase detection pixels having photosensitive regions with different and asymmetric angular responses in accordance with an embodiment.

FIGS. 3B and 3C are cross-sectional views of the phase detection pixels of FIG. 3A in accordance with an embodiment.

FIG. 4 is a diagram of illustrative signal outputs of photosensitive regions of depth sensing pixels for incident light striking the depth sensing pixels at varying angles of incidence in accordance with an embodiment.

FIG. 5 is a cross-sectional side view of a phase detection pixel group in a front-side illuminated image sensor in accordance with an embodiment.

FIG. 6 is a top view of a phase detection pixel group in a front-side illuminated image sensor with a 2×2 arrangement in accordance with an embodiment.

FIG. 7 is a top view of a phase detection pixel group in a front-side illuminated image sensor with a 2×1 arrangement in accordance with an embodiment.

FIG. 8 is a cross-sectional side view of a phase detection pixel group in a front-side illuminated image sensor with both per-pixel microlenses and a per-group microlens in accordance with an embodiment.

FIG. 9 is a top view of a phase detection pixel group in a 2×2 arrangement with both per-pixel microlenses and a per-group microlens in accordance with an embodiment.

FIG. 10 is a top view of a phase detection pixel group in a 2×1 arrangement with both per-pixel microlenses and a per-group microlens in accordance with an embodiment.

FIG. 11 is a cross-sectional side view of a phase detection pixel group in a front-side illuminated image sensor with per-pixel microlenses, a per-group microlens, and a color filter element between the per-pixel microlenses and the per-group microlens in accordance with an embodiment.

FIG. 12 is a cross-sectional side view of a phase detection pixel group in a back-side illuminated image sensor with both per-pixel microlenses and a per-group microlens in accordance with an embodiment.

### DETAILED DESCRIPTION

Embodiments of the present invention relate to image sensors. It will be recognized by one skilled in the art that the present exemplary embodiments may be practiced without some or all of these specific details. In other instances, well-known operations have not been described in detail in order not to unnecessarily obscure the present embodiments.

Electronic devices such as digital cameras, computers, cellular telephones, and other electronic devices may include image sensors that gather incoming light to capture an image. The image sensors may include arrays of pixels. The pixels in the image sensors may include photosensitive elements such as photodiodes that convert the incoming light into image signals. Image sensors may have any number of pixels (e.g., hundreds or thousands or more). A typical image sensor may, for example, have hundreds of thousands or millions of pixels (e.g., megapixels). Image sensors may include control circuitry such as circuitry for operating the pixels and readout circuitry for reading out image signals corresponding to the electric charge generated by the photosensitive elements.

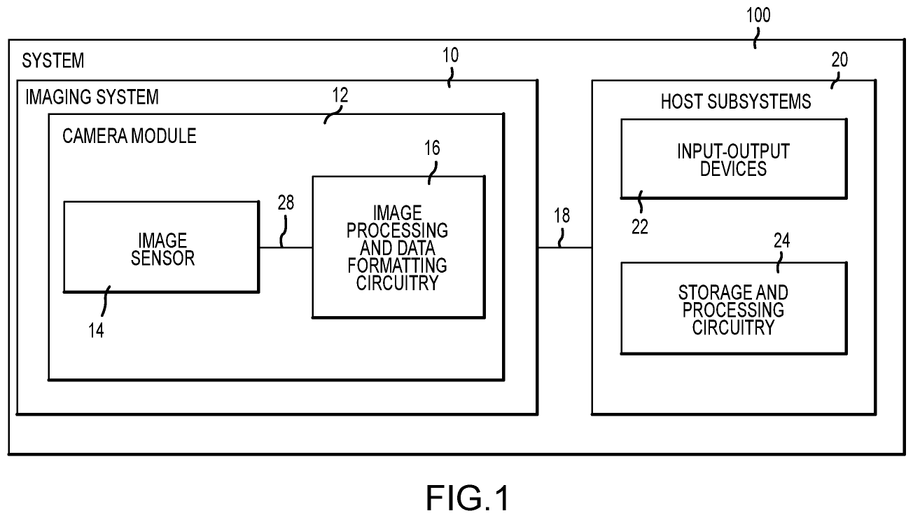

FIG. 1 is a diagram of an illustrative imaging and response system including an imaging system that uses an image sensor to capture images. System 100 of FIG. 1 may be an electronic device such as a camera, a cellular telephone, a video camera, or other electronic device that captures digital image data, may be a vehicle safety system (e.g., an active braking system or other vehicle safety system), may be a surveillance system, or may be any other desired type of system.

As shown in FIG. 1, system 100 may include an imaging system such as imaging system 10 and host subsystems such as host subsystem 20. Imaging system 10 may include camera module 12. Camera module 12 may include one or more image sensors 14 and one or more lenses.

Each image sensor in camera module 12 may be identical or there may be different types of image sensors in a given image sensor array integrated circuit. During image capture operations, each lens may focus light onto an associated image sensor 14. Image sensor 14 may include photosensitive elements (i.e., pixels) that convert the light into digital data. Image sensors may have any number of pixels (e.g., hundreds, thousands, millions, or more). A typical image sensor may, for example, have millions of pixels (e.g., megapixels). As examples, image sensor 14 may include bias circuitry (e.g., source follower load circuits), sample and hold circuitry, correlated double sampling (CDS) circuitry, amplifier circuitry, analog-to-digital converter circuitry, data output circuitry, memory (e.g., buffer circuitry), address circuitry, etc.

Still and video image data from camera sensor 14 may be provided to image processing and data formatting circuitry 16 via path 28. Path 28 may be a connection through a serializer/deserializer (SERDES) which is used for high speed communication and may be especially useful in automotive systems. Image processing and data formatting circuitry 16 may be used to perform image processing functions such as data formatting, adjusting white balance and exposure, implementing video image stabilization, face detection, etc. Image processing and data formatting circuitry 16 may also be used to compress raw camera image files if desired (e.g., to Joint Photographic Experts Group or JPEG format). In a typical arrangement, which is sometimes referred to as a system on chip (SOC) arrangement, camera sensor 14 and image processing and data formatting circuitry 16 are implemented on a common semiconductor substrate (e.g., a common silicon image sensor integrated circuit die). If desired, camera sensor 14 and image processing circuitry 16 may be formed on separate semiconductor substrates. For example, camera sensor 14 and image processing circuitry 16 may be formed on separate substrates that have been stacked.

Imaging system 10 (e.g., image processing and data formatting circuitry 16) may convey acquired image data to host subsystem 20 over path 18. Path 18 may also be a connection through SERDES. Host subsystem 20 may include processing software for detecting objects in images, detecting motion of objects between image frames, determining distances to objects in images, filtering or otherwise processing images provided by imaging system 10.

If desired, system 100 may provide a user with numerous high-level functions. In a computer or advanced cellular telephone, for example, a user may be provided with the ability to run user applications. To implement these functions, host subsystem 20 of system 100 may have input-output devices 22 such as keypads, input-output ports, joysticks, and displays and storage and processing circuitry 24. Storage and processing circuitry 24 may include volatile and nonvolatile memory (e.g., random-access memory, flash memory, hard drives, solid-state drives, etc.). Storage and processing circuitry 24 may also include microprocessors, microcontrollers, digital signal processors, application specific integrated circuits, etc.

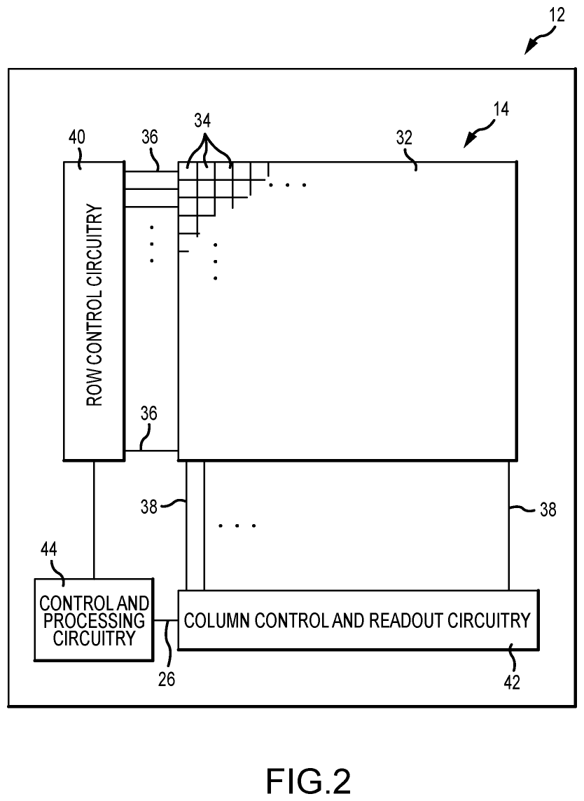

An example of an arrangement for camera module 12 of FIG. 1 is shown in FIG. 2. As shown in FIG. 2, camera module 12 includes image sensor 14 and control and processing circuitry 44. Control and processing circuitry 44 may correspond to image processing and data formatting circuitry 16 in FIG. 1. Image sensor 14 may include a pixel array such as array 32 of pixels 34 (sometimes referred to herein as image sensor pixels, imaging pixels, or image pixels 34) and may also include control circuitry 40 and 42. Control and processing circuitry 44 may be coupled to row control circuitry 40 and may be coupled to column control and readout circuitry 42 via data path 26. Row control circuitry 40 may receive row addresses from control and processing circuitry 44 and may supply corresponding row control signals to image pixels 34 over control paths 36 (e.g., dual conversion gain control signals, pixel reset control signals, charge transfer control signals, blooming control signals, row select control signals, or any other desired pixel control signals). Column control and readout circuitry 42 may be coupled to the columns of pixel array 32 via one or more conductive lines such as column lines 38. Column lines 38 may be coupled to each column of image pixels 34 in image pixel array 32 (e.g., each column of pixels may be coupled to a corresponding column line 38). Column lines 38 may be used for reading out image signals from image pixels 34 and for supplying bias signals (e.g., bias currents or bias voltages) to image pixels 34. During image pixel readout operations, a pixel row in image pixel array 32 may be selected using row control circuitry 40 and image data associated with image pixels 34 of that pixel row may be read out by column control and readout circuitry 42 on column lines 38.

Column control and readout circuitry 42 may include column circuitry such as column amplifiers for amplifying signals read out from array 32, sample and hold circuitry for sampling and storing signals read out from array 32, analog-to-digital converter circuits for converting read out analog signals to corresponding digital signals, and column memory for storing the read out signals and any other desired data. Column control and readout circuitry 42 may output digital pixel values to control and processing circuitry 44 over line 26.

Array 32 may have any number of rows and columns. In general, the size of array 32 and the number of rows and columns in array 32 will depend on the particular implementation of image sensor 14. While rows and columns are generally described herein as being horizontal and vertical, respectively, rows and columns may refer to any grid-like structure (e.g., features described herein as rows may be arranged vertically and features described herein as columns may be arranged horizontally).

Pixel array 32 may be provided with a color filter array having multiple color filter elements which allows a single image sensor to sample light of different colors. As an example, image sensor pixels such as the image pixels in array 32 may be provided with a color filter array which allows a single image sensor to sample red, green, and blue (RGB) light using corresponding red, green, and blue image sensor pixels arranged in a Bayer mosaic pattern. The Bayer mosaic pattern consists of a repeating unit cell of two-by-two image pixels, with two green image pixels diagonally opposite one another and adjacent to a red image pixel diagonally opposite to a blue image pixel. In another suitable example, the green pixels in a Bayer pattern are replaced by broadband image pixels having broadband color filter elements (e.g., clear color filter elements, yellow color filter elements, etc.). These examples are merely illustrative and, in general, color filter elements of any desired color and in any desired pattern may be formed over any desired number of image pixels 34.

If desired, array 32 may be part of a stacked-die arrangement in which pixels 34 of array 32 are split between two or more stacked substrates. In such an arrangement, each of the pixels 34 in the array 32 may be split between the two dies at any desired node within the pixel. As an example, a node such as the floating diffusion node may be formed across two dies. Pixel circuitry that includes the photodiode and the circuitry coupled between the photodiode and the desired node (such as the floating diffusion node, in the present example) may be formed on a first die, and the remaining pixel circuitry may be formed on a second die. The desired node may be formed on (i.e., as a part of) a coupling structure (such as a conductive pad, a micro-pad, a conductive interconnect structure, or a conductive via) that connects the two dies. Before the two dies are bonded, the coupling structure may have a first portion on the first die and may have a second portion on the second die. The first die and the second die may be bonded to each other such that first portion of the coupling structure and the second portion of the coupling structure are bonded together and are electrically coupled. If desired, the first and second portions of the coupling structure may be compression bonded to each other. However, this is merely illustrative. If desired, the first and second portions of the coupling structures formed on the respective first and second dies may be bonded together using any metal-to-metal bonding technique, such as soldering or welding.

As mentioned above, the desired node in the pixel circuit that is split across the two dies may be a floating diffusion node. Alternatively, the desired node in the pixel circuit that is split across the two dies may be the node between a floating diffusion region and the gate of a source follower transistor (i.e., the floating diffusion node may be formed on the first die on which the photodiode is formed, while the coupling structure may connect the floating diffusion node to the source follower transistor on the second die), the node between a floating diffusion region and a source-drain node of a transfer transistor (i.e., the floating diffusion node may be formed on the second die on which the photodiode is not located), the node between a source-drain node of a source follower transistor and a row select transistor, or any other desired node of the pixel circuit.

In general, array 32, row control circuitry 40, column control and readout circuitry 42, and control and processing circuitry 44 may be split between two or more stacked substrates. In one example, array 32 may be formed in a first substrate and row control circuitry 40, column control and readout circuitry 42, and control and processing circuitry 44 may be formed in a second substrate. In another example, array 32 may be split between first and second substrates (using one of the pixel splitting schemes described above) and row control circuitry 40, column control and readout circuitry 42, and control and processing circuitry 44 may be formed in a third substrate.

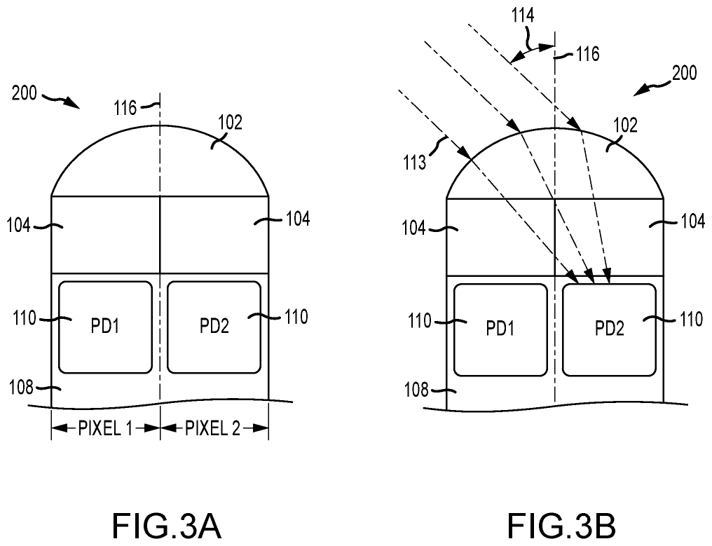

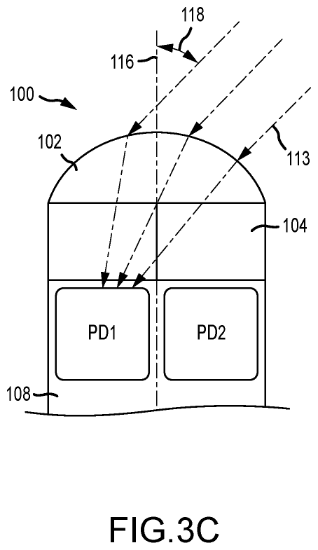

It may be desirable to provide image sensors with depth sensing capabilities (e.g., to use in automatic focusing applications, 3D imaging applications such as machine vision applications, etc.). To provide depth sensing capabilities, image sensor 14 may include phase detection pixel groups such as phase detection pixel group 200 shown in FIG. 3A. If desired, pixel groups that provide depth sensing capabilities may also provide high dynamic range functionalities.

FIG. 3A is an illustrative cross-sectional view of pixel group 200. In FIG. 3A, phase detection pixel group 200 is a pixel pair. Pixel pair 200 may include first and second pixels such Pixel 1 and Pixel 2. Pixel 1 and Pixel 2 may include photosensitive regions such as photosensitive regions 110 formed in a semiconductor substrate such as silicon substrate 108. For example, Pixel 1 may include an associated photosensitive region such as photodiode PD1, and Pixel 2 may include an associated photosensitive region such as photodiode PD2. A microlens may be formed over photodiodes PD1 and PD2 and may be used to direct incident light towards photodiodes PD1 and PD2. The arrangement of FIG. 3A in which microlens 102 covers two pixel regions may sometimes be referred to as a 2×1 or 1×2 arrangement because there are two phase detection pixels arranged consecutively in a line. In an alternate embodiment, three phase detection pixels may be arranged consecutively in a line in what may sometimes be referred to as a 1×3 or 3×1 arrangement. In other embodiments, phase detection pixels may be grouped in a 2×2 or 2×4 arrangement. In general, phase detection pixels may be arranged in any desired manner.

Color filters such as color filter elements 104 may be interposed between microlens 102 and substrate 108. Color filter elements 104 may filter incident light by only allowing predetermined wavelengths to pass through color filter elements 104 (e.g., color filter 104 may only be transparent to the wavelengths corresponding to a green color, a red color, a blue color, a yellow color, a cyan color, a magenta color, visible light, infrared light, etc.). Color filter 104 may be a broadband color filter. Examples of broadband color filters include yellow color filters (e.g., yellow color filter material that passes red and green light) and clear color filters (e.g., transparent material that passes red, blue, and green light). In general, broadband filter elements may pass two or more colors of light. Photodiodes PD1 and PD2 may serve to absorb incident light focused by microlens 102 and produce pixel signals that correspond to the amount of incident light absorbed.

Photodiodes PD1 and PD2 may each cover approximately half of the substrate area under microlens 102 (as an example). By only covering half of the substrate area, each photosensitive region may be provided with an asymmetric angular response (e.g., photodiode PD1 may produce different image signals based on the angle at which incident light reaches pixel pair 200). The angle at which incident light reaches pixel pair 200 relative to a normal axis 116 (i.e., the angle at which incident light strikes microlens 102 relative to the optical axis 116 of lens 102) may be herein referred to as the incident angle or angle of incidence.

An image sensor can be formed using front-side illumination imager arrangements (e.g., when circuitry such as metal interconnect circuitry is interposed between the microlens and photosensitive regions) or back-side illumination imager arrangements (e.g., when photosensitive regions are interposed between the microlens and the metal interconnect circuitry). The example of FIGS. 3A, 3B, and 3C in which pixels 1 and 2 are back-side illuminated image sensor pixels is merely illustrative. If desired, pixels 1 and 2 may be front-side illuminated image sensor pixels.

In the example of FIG. 3B, incident light 113 may originate from the left of normal axis 116 and may reach pixel pair 200 with an angle 114 relative to normal axis 116. Angle 114 may be a negative angle of incident light. Incident light 113 that reaches microlens 102 at a negative angle such as angle 114 may be focused towards photodiode PD2. In this scenario, photodiode PD2 may produce relatively high image signals, whereas photodiode PD1 may produce relatively low image signals (e.g., because incident light 113 is not focused towards photodiode PD1).

In the example of FIG. 3C, incident light 113 may originate from the right of normal axis 116 and reach pixel pair 200 with an angle 118 relative to normal axis 116. Angle 118 may be a positive angle of incident light. Incident light that reaches microlens 102 at a positive angle such as angle 118 may be focused towards photodiode PD1 (e.g., the light is not focused towards photodiode PD2). In this scenario, photodiode PD2 may produce an image signal output that is relatively low, whereas photodiode PD1 may produce an image signal output that is relatively high.

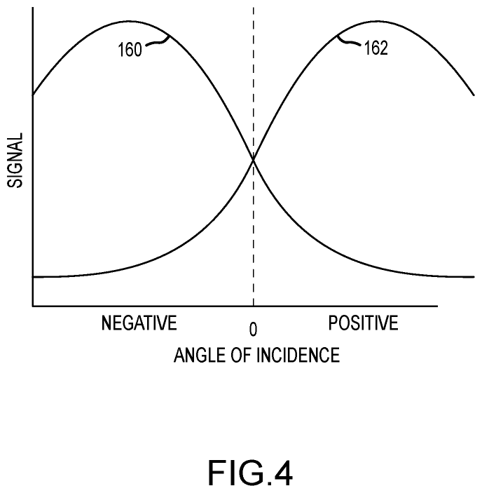

The positions of photodiodes PD1 and PD2 may sometimes be referred to as asymmetric or displaced positions because the center of each photosensitive area 110 is offset from (i.e., not aligned with) optical axis 116 of microlens 102. Due to the asymmetric formation of individual photodiodes PD1 and PD2 in substrate 108, each photosensitive area 110 may have an asymmetric angular response (e.g., the signal output produced by each photodiode 110 in response to incident light with a given intensity may vary based on an angle of incidence). It should be noted that the example of FIGS. 3A-3C where the photodiodes are adjacent is merely illustrative. If desired, the photodiodes may not be adjacent (i.e., the photodiodes may be separated by one or more intervening photodiodes). In the diagram of FIG. 4, an example of the image signal outputs of photodiodes PD1 and PD2 of pixel pair 200 in response to varying angles of incident light is shown.

Line 160 may represent the output image signal for photodiode PD2 whereas line 162 may represent the output image signal for photodiode PD1. For negative angles of incidence, the output image signal for photodiode PD2 may increase (e.g., because incident light is focused onto photodiode PD2) and the output image signal for photodiode PD1 may decrease (e.g., because incident light is focused away from photodiode PD1). For positive angles of incidence, the output image signal for photodiode PD2 may be relatively small and the output image signal for photodiode PD1 may be relatively large.

The size and location of photodiodes PD1 and PD2 of pixel pair 200 of FIGS. 3A, 3B, and 3C are merely illustrative. If desired, the edges of photodiodes PD1 and PD2 may be located at the center of pixel pair 200 or may be shifted slightly away from the center of pixel pair 200 in any direction. If desired, photodiodes 110 may be decreased in size to cover less than half of the pixel area.

Output signals from pixel pairs such as pixel pair 200 may be used to adjust the optics (e.g., one or more lenses) in image sensor 14 during automatic focusing operations. The direction and magnitude of lens movement needed to bring an object of interest into focus may be determined based on the output signals from pixel pairs 200.

For example, by creating pairs of pixels that are sensitive to light from one side of the lens or the other, a phase difference can be determined. This phase difference may be used to determine both how far and in which direction the image sensor optics should be adjusted to bring the object of interest into focus.

When an object is in focus, light from both sides of the image sensor optics converges to create a focused image. When an object is out of focus, the images projected by two sides of the optics do not overlap because they are out of phase with one another. By creating pairs of pixels where each pixel is sensitive to light from one side of the lens or the other, a phase difference can be determined. This phase difference can be used to determine the direction and magnitude of optics movement needed to bring the images into phase and thereby focus the object of interest. Pixel blocks that are used to determine phase difference information such as pixel pair 200 are sometimes referred to herein as phase detection pixels or depth-sensing pixels.

A phase difference signal may be calculated by comparing the output pixel signal of PD1 with that of PD2. For example, a phase difference signal for pixel pair 200 may be determined by subtracting the pixel signal output of PD1 from the pixel signal output of PD2 (e.g., by subtracting line 162 from line 160). For an object at a distance that is less than the focused object distance, the phase difference signal may be negative. For an object at a distance that is greater than the focused object distance, the phase difference signal may be positive. This information may be used to automatically adjust the image sensor optics to bring the object of interest into focus (e.g., by bringing the pixel signals into phase with one another).

As previously mentioned, the example in FIGS. 3A-3C where phase detection pixel block 200 includes two adjacent pixels is merely illustrative. In another illustrative embodiment, phase detection pixel block 200 may include multiple adjacent pixels that are covered by varying types of microlenses (e.g., toroidal, circular, elliptical, etc.).

It should be understood that there are various nomenclature options for describing the arrangements of the type shown herein. In one example, the photosensitive areas covered by a given microlens may be referred to as a phase detection pixel group (or phase detection pixel block) and each photosensitive area may be referred to as a phase detection pixel (or as part of a phase detection pixel). However, in another example, the photosensitive areas covered by a given microlens may be referred to as a phase detection pixel and each photosensitive area may be referred to as a sub-pixel. Herein, the terminology of a phase detection pixel group including a number of phase detection pixels will generally be used.

The image sensor may optionally include both phase detection pixels (e.g., pixels that have asymmetric responses to incident light) and imaging pixels (e.g., pixels that have symmetric responses to incident light). In general, each imaging pixel may be covered by a single corresponding microlens, whereas multiple phase detection pixels may be covered by a single corresponding microlens (as in FIG. 3A, for example).

As previously mentioned, the imaging pixels in image sensor 14 may be front-side illuminated imaging pixels. FIG. 5 is a cross-sectional side view of an illustrative phase detection pixel group that includes FSI phase detection pixels. Similar to the BSI pixels of FIG. 3A, the FSI phase detection pixels of FIG. 5 include photodiodes 110 formed in substrate 108. The photodiodes may be covered by a microlens 102 and color filter element 104, as in FIG. 3A. However, in FIG. 5 the FSI pixels also include interlayer dielectric layers 202 (sometimes referred to as dielectric layers 202 or interlayer dielectric 202) with metal routing 204. The interlayer dielectric layers and metal routing 204 may be used to form circuitry that is used to operate the image sensor.

The interlayer dielectric 202 and metal routing structures 204 formed between the microlens 102 and photodiodes 110 may block incident light from reaching photodiodes 110. To help guide light to photodiodes 110, the phase detection pixels may each include a light pipe 206. The light pipes may guide light to the front surface 210 and photodiodes 110 using total internal reflection. A planarization layer 212 may be formed between color filter element 104 and microlens 102.

The components of FIG. 5 may be formed from any desired materials. Planarization layer 212 may be formed from silicon oxide, silicon nitride, or any other desired material. Interlayer dielectric layers (ILDs) 202 may be formed from oxide layers or any other desired materials. Light pipes 206 may be formed from a high-index layer (e.g., a material having a higher index of refraction than ILDs 202). The material that forms light pipes 206 may have an index of refraction between 1.65 and 1.80 in one example.

The microlens 102 may focus some of the incident light (e.g., light rays 216) on area 214 that is between light pipes 206. This is undesirable, as incident light focused on area 214 enters into interlayer dielectric layers 202 and is unlikely to be received by the photodiodes 110 and converted into detectable charge. Therefore, this light is lost and results in decreased efficiency of the image sensor.

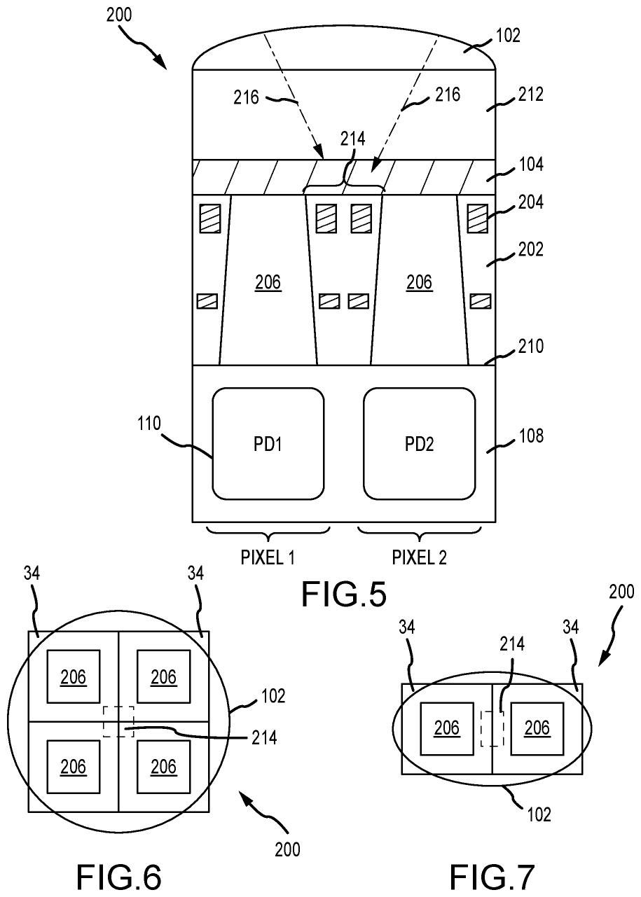

FIGS. 6 and 7 are top views of illustrative phase detection pixel groups 200. FIG. 6 is a top view of a phase detection pixel group with a 2×2 arrangement of pixels. As shown, microlens 102 may cover four phase detection pixels 34 that each have a respective photodiode (e.g., photosensitive area 110) covered by a light pipe 206. As shown, there are gaps between the light pipes 206 where the incident light may enter the interlayer dielectric layers. For example, light may be focused on area 214 between the light pipes by microlens 102 and therefore not be converted to charge by the photodiodes.

FIG. 7 is a top view of a phase detection pixel group with a 2×1 arrangement of pixels. As shown, microlens 102 may cover two phase detection pixels 34 that each have a respective photodiode (e.g., photosensitive area 110) covered by a light pipe 206. As shown, there are gaps between the light pipes 206 where the incident light may enter the interlayer dielectric layers. For example, light may be focused on area 214 between the light pipes by microlens 102 and therefore not be converted to charge by the photodiodes.

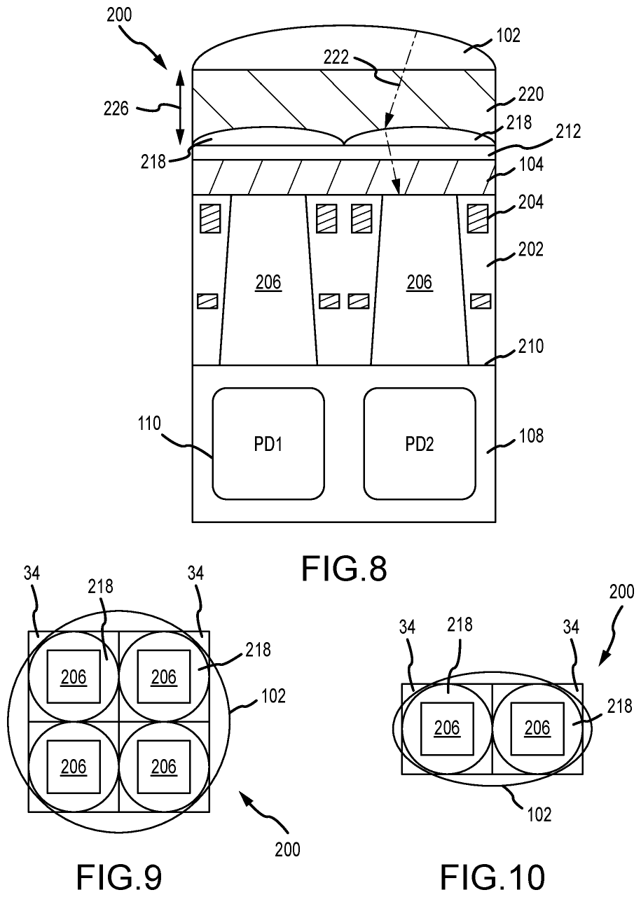

To avoid losing incident light to the areas between light pipes 206 and therefore increase the efficiency of the pixels, the phase detection pixels may include additional microlenses. FIG. 8 is a cross-sectional side view of FSI phase detection pixels covered by both per-pixel microlenses and a per-group microlens. Similar to the pixels of FIG. 5, the FSI imaging pixels of FIG. 8 include photodiodes 110 formed in substrate 108. The FSI pixels also include interlayer dielectric layers 202 with metal routing 204. The interlayer dielectric layers and metal routing 204 may be used to form circuitry that is used to operate the image sensor. To help guide light to photodiodes 110, the phase detection pixels may each include a light pipe 206. The light pipes may guide light to the front surface 210 and photodiodes 110 using total internal reflection.

Phase detection pixel group 200 includes a microlens 102 that covers all of the pixels in the phase detection pixel group. Microlens 102 may therefore sometimes be referred to as a per-group microlens or a per-phase-detection-pixel-group microlens. In addition to microlens 102, phase detection pixel group 200 also includes microlenses 218. Each light pipe 206 (and photodiode 110) may be covered by a respective microlens 218.

Color filter element 104 may be formed over light pipes 206. Planarization layer 212 may be interposed between color filter element 104 and microlenses 218. A low-index filler 220 may be formed between microlenses 218 and microlens 102. The low-index filler may conform to the curved upper surfaces of microlenses 218.

Per-pixel microlenses 218 may help capture light that would otherwise be lost between the light pipes. As an example, consider light ray 222. Without microlenses 218, light ray 222 would be directed by microlens 102 to the space between the phase detection pixels. However, microlens 218 instead focuses the light into light pipe 206 where the light may be captured by the underlying photodiodes.

The components of FIG. 8 may be formed from any desired materials. Planarization layer 212 may be formed from silicon oxide, silicon nitride, or any other desired material. Interlayer dielectric layers (ILDs) 202 may be formed from oxide layers or any other desired materials. Light pipes 206 may be formed from a high-index layer (e.g., a material having a higher index of refraction than ILDs 202). The material that forms light pipes 206 may have an index of refraction between 1.65 and 1.80 in one example. Low-index filler 220 may be formed from a material with a lower refractive index than microlenses 218. In one example, low-index filler 220 may be formed from a mix of hollow particles (e.g., organic particles or inorganic particles) suspended in an organic matrix. The hollow particles may be filled with a gas (e.g., air), lowering the index of refraction of the material. In another possible embodiment, low-index filler may be formed from an oxide material, a polymer material (e.g., a spin-on polymer), etc. In general, low-index filler 220 may be formed from any desired material. The thickness 226 of low-index material may be selected to optimize the efficiency of the pixels.

Microlenses 102 and 218 may also be formed from any desired materials. The microlenses may be formed by etching (e.g., a layer of material is deposited then etched to form the desired microlens shapes) or reflow (e.g., a layer of material is patterned and then heated to form the desired microlens shapes). The microlenses may be formed from polymer material, silicon nitride, or any other desired material.

In general, it may be desirable for microlens 218 to have a higher index of refraction than low-index filler 220. Microlens 218 may therefore be formed from a different material than microlens 102. In particular, microlens 218 may have a higher index of refraction than microlens 102. In one arrangement, microlens 102 may be formed from a polymer material and microlens 218 may be formed from silicon nitride.

FIGS. 9 and 10 are top views of illustrative phase detection pixel groups 200. FIG. 9 is a top view of a phase detection pixel group with a 2x2 arrangement of pixels. As shown, microlens 102 may cover four phase detection pixels 34 that each have a respective photodiode (e.g., photosensitive area 110) covered by a light pipe 206. Additionally, each light pipe 206 is covered by a respective per-pixel microlens 218.

FIG. 10 is a top view of a phase detection pixel group with a 2x1 arrangement of pixels. As shown, microlens 102 may cover two phase detection pixels 34 that each have a respective photodiode (e.g., photosensitive area 110) covered by a light pipe 206. Additionally, each light pipe 206 is covered by a respective per-pixel microlens 218.

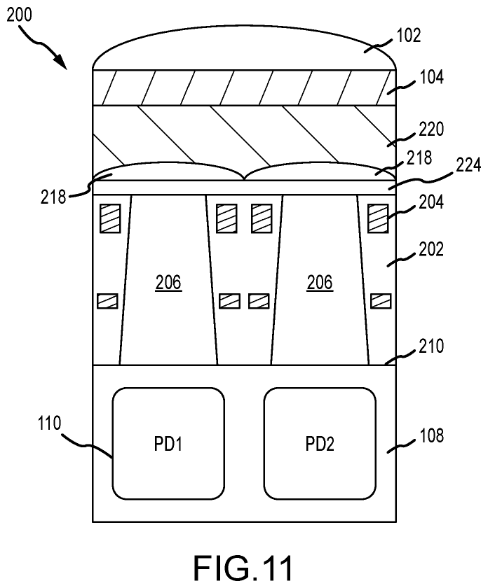

The example of FIG. 8 of color filter element 104 and planarization layer 212 being formed between microlenses 218 and light pipes 206 is merely illustrative. In another possible arrangement, shown in FIG. 11, microlenses 218 are formed on light pipes 206. An optional anti-reflective coating (ARC) 224 may be interposed between microlenses 218 and light pipes 206. Microlenses 218 may be covered by conformal low-index layer 220. The low-index layer 220 is interposed between microlenses 218 and color filter element 104. Color filter element 104 is interposed between low-index layer 220 and microlens 102. In one example, microlenses 218 in FIG. 11 may be formed from silicon nitride and low-index layer 220 may be formed from an oxide material.

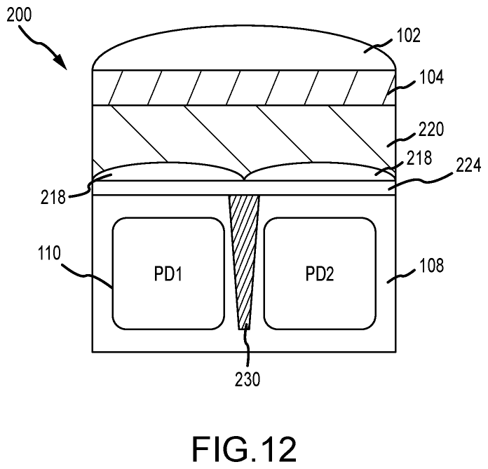

The examples of FIGS. 8 and 11 of an FSI image sensor including phase detection pixels covered by both per-pixel microlenses and overlapping per-group microlenses are merely illustrative. This concept may be applied to BSI image sensors as well. FIG. 12 is a cross-sectional side view of a BSI image sensor of this type.

As shown in FIG. 12, the BSI imaging pixels include photodiodes 110 formed in substrate 108. Additionally, deep trench isolation (DTI) 230 may be formed in substrate 108 between adjacent photodiodes. The deep trench isolation may be formed in a grid between the array of phase detection pixels and may be formed from a material (e.g., a metal or oxide) deposited in a trench in substrate 108.

Per-pixel microlenses 218 may prevent light from being focused onto DTI 230 by microlens 102. As shown in FIG. 12, microlenses 218 may be formed on substrate 108 with an optional intervening anti-reflective coating 224. In some embodiments, microlenses 218 may be formed directly on substrate 108. Low-index filler 220 is then formed over microlenses 218 and color filter element 104 is interposed between low-index filler 220 and microlens 102. This example is merely illustrative. If desired, the stack-up of FIG. 8 (with color filter element 104 below microlenses 218) may be used in a BSI image sensor as well.

The examples provided herein are merely illustrative. If desired, additional planarization layers may be included in the image sensors (e.g., between low-index layer 220 and color filter element 104 in FIG. 11 or FIG. 12, between ARC 224 and microlenses 218 in FIG. 12, etc.). Any of the material options described herein may be used in any of the possible arrangements. An anti-reflective coating may be incorporated into any of the possible arrangements. Any of the stack-up options for the microlenses 218, color filter element 104, and low-index filler 220 may be used for BSI image sensors or FSI image sensors.

The depicted examples of 2×2 phase detection pixel groups and 2×1 phase detection pixel groups are also merely illustrative. In general, a phase detection pixel group of any desired size (e.g., 3×3, 3×1, 4×4, etc.) may include microlenses (e.g., per-pixel microlenses 218) over each phase detection pixel and a single microlens (e.g., per-group microlens 102) over the phase detection pixel group.

Additionally, in the examples depicted herein each phase detection pixel group includes a color filter element of a single color (e.g., each phase detection pixel in the group is covered by color filter material of the same color). The phase detection pixel groups may be covered by a color filter pattern (e.g., a Bayer pattern or other desired pattern). Alternatively, different phase detection pixels within a single group may be covered by different color filter elements if desired (e.g., PD1 and PD2 in FIG. 12 may be covered by color filter elements of different colors).

The foregoing is merely illustrative of the principles of this invention and various modifications can be made by those skilled in the art. The foregoing embodiments may be implemented individually or in any combination.

What is claimed is:

1. An image sensor comprising:
a substrate;
at least first and second photosensitive areas in the substrate;
first and second microlenses that respectively cover the first and second photosensitive areas;
a third microlens that covers the first and second photosensitive areas, wherein the first and second microlenses are interposed between the substrate and the third microlens; and
a low-index filler that is interposed between the first and second microlenses and the third microlens.

2. The image sensor defined in claim 1, further comprising:
a color filter element that is interposed between the substrate and the first and second microlenses.

3. The image sensor defined in claim 2, further comprising:
a planarization layer that is interposed between the color filter element and the first and second microlenses.

4. The image sensor defined in claim 1, further comprising:
interlayer dielectric layers; and
first and second light pipes formed over the first and second photosensitive areas, wherein the first and second light pipes extend through the interlayer dielectric layers and wherein the first and second microlenses respectively cover the first and second light pipes.

5. The image sensor defined in claim 4, wherein the first and second light pipes are formed from a material having a higher index of refraction than the interlayer dielectric layers.

6. The image sensor defined in claim 1, wherein the low-index filler has a lower index of refraction than the first and second microlenses.

7. The image sensor defined in claim 6, wherein the low-index filler comprises air-filled inorganic particles suspended in an organic matrix.

8. The image sensor defined in claim 6, wherein the low-index filler conforms to respective first and second curved upper surfaces of the first and second microlenses.

9. The image sensor defined in claim 1, further comprising:
a color filter element that is interposed between the low-index filler and the third microlens.

10. The image sensor defined in claim 1, further comprising:
an anti-reflective coating that is interposed between the first and second microlenses and the first and second photosensitive areas.

11. The image sensor defined in claim 1, further comprising:
deep trench isolation that is formed in the substrate between the first and second photosensitive areas.

12. An image sensor that includes a phase detection pixel group, the phase detection pixel group comprising:
at least two phase detection pixels with respective photosensitive areas;
at least two per-pixel microlenses that each cover a respective photosensitive area of the photosensitive areas; and
a per-group microlens that covers all of the at least two phase detection pixels in the phase detection pixel group, wherein the per-group microlens overlaps the at least two per-pixel microlenses.

13. The image sensor defined in claim 12, wherein each one of the at least two per-pixel microlenses has a respective curved upper surface and wherein the per-group microlens has a curved upper surface.

14. The image sensor defined in claim 12, wherein the phase detection pixel group further comprises:
a low-index filler that is interposed between the at least two per-pixel microlenses and the per-group microlens.

15. The image sensor defined in claim 14, wherein the phase detection pixel group further comprises:
a color filter element that is interposed between the low-index filler and the per-group microlens.

16. The image sensor defined in claim 12, wherein the phase detection pixel group further comprises:
a color filter element that is interposed between the photosensitive areas and the at least two per-pixel microlenses.

17. The image sensor defined in claim 12, wherein the phase detection pixel group further comprises:
at least two light pipes, wherein each light pipe is interposed between a respective photosensitive area and a respective per-pixel microlens.

18. The image sensor defined in claim 12, wherein the image sensor is a front-side illuminated image sensor and wherein the phase detection pixel group further comprises:
at least two light pipes that guide incident light to the photosensitive areas of the at least two phase detection pixels.

19. The image sensor defined in claim 12, wherein the image sensor is a back-side illuminated image sensor and wherein the phase detection pixel group further comprises:
deep trench isolation that is interposed between the photosensitive areas of the at least two phase detection pixels.

20. A front-side illuminated image sensor comprising:
a substrate;
first and second photosensitive areas in the substrate;
dielectric layers formed over the substrate that include metal routing structures;
first and second light pipes that guide light through the dielectric layers and that respectively overlap the first and second photosensitive areas;
first and second microlenses that respectively overlap the first and second light pipes; and
a third microlens that overlaps both the first and second microlenses.
